(19) United States
(12) Patent Application Publication
(10) Pub. No.: US 2025/0132269 A1
(43) Pub. Date: Apr. 24, 2025

(54) SEMICONDUCTOR DEVICE

(71) Applicant: Murata Manufacturing Co., Ltd., Kyoto-fu (JP)

(72) Inventor: Shinya MASUNO, Nagaokakyo-shi (JP)

(73) Assignee: Murata Manufacturing Co., Ltd., Kyoto-fu (JP)

(21) Appl. No.: 18/906,268

(22) Filed: Oct. 4, 2024

(30) Foreign Application Priority Data
Oct. 19, 2023 (JP) 2023-180427

(51) Int. Cl. H01L 23/00; H01L 21/78; H01L 23/58; H01L 27/12; H01L 29/78

(52) U.S. Cl. CPC H01L 23/564; H01L 21/78; H01L 23/562; H01L 23/585; H10D 30/637; H10D 86/201

(57) ABSTRACT

An insulating layer made of an inorganic insulating material is provided on an upper surface which is one surface of a support substrate made of a polymer or a filler-containing polymer. A circuit formation layer including a semiconductor element is provided on the insulating layer. A lower surface on an opposite side from the upper surface and a side surface of the support substrate are covered with a coating film formed of a material having lower moisture permeability than the support substrate.

### CROSS-REFERENCE TO RELATED APPLICATION

This application claims benefit of priority to Japanese Patent Application No. 2023-180427, filed Oct. 19, 2023, the entire content of which is incorporated herein by reference.

### BACKGROUND

### Technical Field

The present disclosure relates to a semiconductor device.

### Background Art

A semiconductor device including a silicon-on-insulator (SOI)-CMOSFET in which a silicon substrate of an SOI substrate is removed, and a semiconductor layer and an insulating layer made of silicon are transferred to a polymer substrate is disclosed in U.S. Pat. No. 9,812,350. In the semiconductor device disclosed in U.S. Pat. No. 9,812,350, an interfacial adhesion layer is provided at an interface between the polymer substrate and the insulating layer for the purpose of preventing penetration of moisture from the polymer substrate into the insulating layer and the semiconductor layer.

### SUMMARY

In the semiconductor device disclosed in U.S. Pat. No. 9,812,350, a decrease in reliability due to penetration of moisture into the insulating layer and the semiconductor layer can be suppressed. However, according to the study by the inventors of the present application, it has been found that electrical characteristics of the semiconductor device fluctuate when the semiconductor device is operated under an environment where moisture is present. It is considered that one of the causes of the fluctuation in the electrical characteristics is distortion generated in the semiconductor layer as a result of expansion of the polymer substrate due to moisture absorption.

Therefore, the present disclosure provides a semiconductor device in which electrical characteristics are less likely to generate fluctuation even when the semiconductor device is operated under an environment where moisture is present.

According to an aspect of the present disclosure, there is provided a semiconductor device including a support substrate made of a polymer or a filler-containing polymer, an insulating layer made of an inorganic insulating material and provided on an upper surface being one surface of the support substrate, a circuit formation layer including a semiconductor element provided on the insulating layer, and a coating film covering a lower surface and a side surface of the support substrate. The lower surface is on an opposite side from the upper surface, and the coating film is formed of a material having lower moisture permeability than the support substrate.

According to another aspect of the present disclosure, there is provided a semiconductor device including a support substrate made of a polymer or a filler-containing polymer, an insulating layer made of an inorganic insulating material and provided on an upper surface being one surface of the support substrate, a circuit formation layer including a semiconductor element provided on the insulating layer, and a coating film covering a lower surface and a side surface of the support substrate. The lower surface is on an opposite side from the upper surface, and the coating film is formed of an inorganic insulating material.

The coating film suppresses penetration of moisture into the support substrate, and thus expansion of the support substrate due to moisture absorption is suppressed. Therefore, the semiconductor element is less likely to generate distortion, and the electrical characteristics are less likely to generate fluctuation caused by the distortion.

### BRIEF DESCRIPTION OF THE DRAWINGS

FIG. 1 is a cross-sectional view of a semiconductor device according to a first embodiment;

FIG. 2A, FIG. 2B, FIG. 2C and FIG. 2D are cross-sectional views of the semiconductor device at an intermediate stage of a manufacturing process according to the first embodiment;

FIG. 3A, FIG. 3B and FIG. 3C are cross-sectional views of the semiconductor device at an intermediate stage of the manufacturing process according to the first embodiment;

FIG. 4 is a cross-sectional view of a semiconductor device according to a modified example of the first embodiment;

FIG. 5 is a cross-sectional view of a semiconductor device according to a second embodiment;

FIG. 6A, FIG. 6B and FIG. 6C are cross-sectional views of the semiconductor device at an intermediate stage of a manufacturing process according to the second embodiment;

FIG. 7 is a cross-sectional view of a semiconductor device according to a modified example of the second embodiment;

FIG. 8 is a cross-sectional view of a semiconductor device according to another modified example of the second embodiment; and

FIG. 9A is a cross-sectional view of a semiconductor device according to a third embodiment and FIG. 9B is a plan cross-sectional view taken along a dashed-dotted line 9B-9B in FIG. 9A.

### DETAILED DESCRIPTION

### First Embodiment

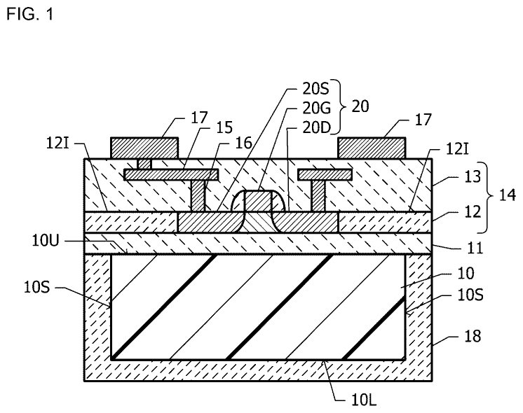

A semiconductor device according to a first embodiment will be described with reference to the drawings from FIG. 1 to FIG. 3C.

FIG. 1 is a cross-sectional view of the semiconductor device according to the first embodiment. An insulating layer 11 made of an inorganic insulating material is provided on one surface (hereinafter, referred to as an upper surface 10U) of a support substrate 10 made of a polymer or a filler-containing polymer. A coating film 18 covers a lower surface 10L on an opposite side from the upper surface 10U and a side surface 10S of the support substrate 10. The coating film 18 is formed of an insulating material having lower moisture permeability than the support substrate 10. An upper end of a portion of the coating film 18 covering the side surface 10S of the support substrate 10 (an end surface along the upper surface 10U of the support substrate 10) is in contact with a lower surface of the insulating layer 11.

The term “low moisture permeability” means that a water vapor transmission rate is low when films having the same thickness each other are compared. The term “water vapor transmission rate” refers to an amount of water vapor that passes through a film-like substance per unit area in a certain time. As an example, when a film-like substance is used as a boundary surface at a constant temperature, for example, 25° C., air on one side is kept at a constant relative humidity, for example, 90%, and air on the other side is kept in a dry state by a moisture absorbent, mass of water vapor passing through the boundary surface for a constant time, for example, 24 hours, is converted into a value per 1 m² of the film-like substance, and the value can be defined as the water vapor transmission rate of the film-like substance.

For example, a filler-containing resin is used for the support substrate 10. As the resin, for example, an epoxy-based resin, a polyimide-based resin, a benzocyclobutene-based resin, or the like is used. The coating film 18 is formed of, for example, an inorganic insulating material such as silicon nitride (SiN), aluminum oxide (Al₂O₃), or diamond-like carbon (DLC). Alternatively, the coating film 18 may be formed of a polymer having lower moisture permeability than the polymer used for the support substrate 10, for example, a liquid crystal polymer (LCP) or the like.

A circuit formation layer 14 is disposed on an upper surface of the insulating layer 11. A semiconductor element 20, for example, a MOSFET 20 is provided in the circuit formation layer 14. More specifically, the circuit formation layer 14 includes a semiconductor layer 12 disposed on the insulating layer 11, the semiconductor element 20 provided in the semiconductor layer 12, and a multilayer wiring layer 13 disposed on the semiconductor layer 12. A plurality of terminals 17 for external connection are provided on the multilayer wiring layer 13.

Part of the semiconductor layer 12 is used as an element isolation region 12I having an insulation property, and an active region surrounded by the element isolation region 12I is defined. The semiconductor element 20 is formed in the active region. The semiconductor element 20 is, for example, a MOSFET including a source region 20S and a drain region 20D disposed in the active region of the semiconductor layer 12, and gate electrodes 20G disposed on an upper surface of the semiconductor layer 12 with a gate insulating film (not illustrated) interposed therebetween. Although only one active region is illustrated in FIG. 1, a plurality of active regions may be provided. The semiconductor element 20 may be a multi-finger type MOSFET.

The multilayer wiring layer 13 includes a plurality of wirings 15 and a plurality of vias 16 disposed inside. Some of the terminals 17 are connected to the semiconductor element 20 with the wiring 15 and the via 16 interposed therebetween. The total thickness of the semiconductor layer 12 and the multilayer wiring layer 13 is, for example, equal to or less than 20 μm. The terminals 17 are formed in a bump structure, for example, and have a height of about 160 μm, for example. A thickness of the insulating layer 11 is preferably, for example, equal to or more than 100 nm and equal to or less than 1500 nm (i.e., from 100 nm to 1500 nm), and more preferably equal to or more than 200 nm and equal to or less than 1000 nm (i.e., from 200 nm to 1000 nm). A thickness of the support substrate 10 is, for example, about 100 μm. A thickness of the coating film 18 is, for example, about 1 μm. Note that, a size of each constituent element illustrated in FIG. 1 does not reflect the actual size.

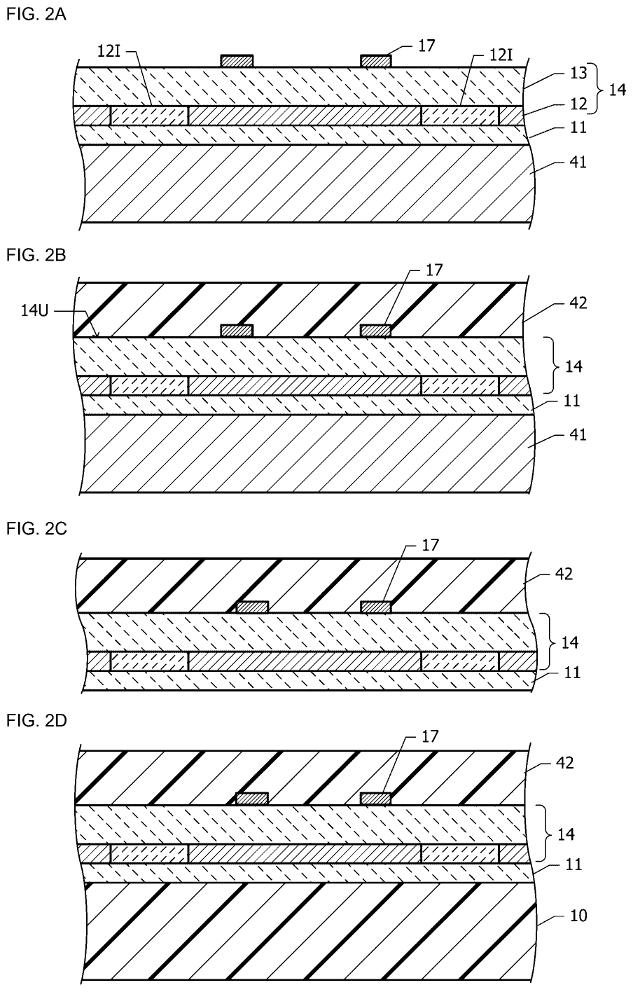

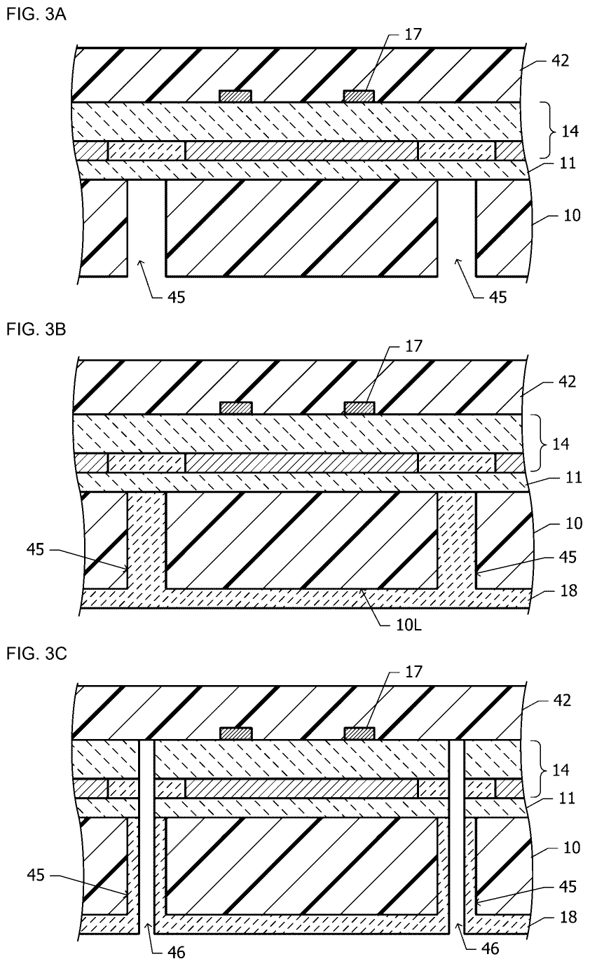

Next, a method of manufacturing the semiconductor device according to the first embodiment will be described with reference to the drawings from FIG. 2A to FIG. 3C. The drawings from FIG. 2A to FIG. 3C are cross-sectional views of the semiconductor device at an intermediate stage of a manufacturing process according to the first embodiment. In the drawings from FIG. 2A to FIG. 3C, the semiconductor elements 20, the wirings 15, the vias 16, and the like of the circuit formation layer 14 are omitted.

As illustrated in FIG. 2A, an SOI substrate including a semiconductor substrate 41, the insulating layer 11, and the semiconductor layer 12 is prepared. The insulating layer 11 included in the SOI substrate is also referred to as a buried silicon oxide layer (BOX layer). The element isolation region 12I, the semiconductor element 20, the multilayer wiring layer 13, the terminals 17 (FIG. 1), and the like are formed on the SOI substrate by using a general semiconductor process technique.

As illustrated in FIG. 2B, a protective tape 42 is attached to upper surfaces of the circuit formation layer 14 and the terminals 17. With the protective tape 42 attached, the semiconductor substrate 41 (FIG. 2B) is removed as illustrated in FIG. 2C. In order to remove the semiconductor substrate 41, for example, wet etching can be applied. Alternatively, backgrinding and chemical mechanical polishing (CMP) may be employed. By removing the semiconductor substrate 41, the insulating layer 11 is exposed.

As illustrated in FIG. 2D, a support substrate 10 made of a filler-containing polymer is provided on the exposed surface of the insulating layer 11. The support substrate 10 is formed by, for example, bonding a polymer sheet by a lamination method and then heating.

As illustrated in FIG. 3A, half-cut dicing is performed from the lower surface 10L of the support substrate 10, thereby forming a groove 45 reaching the lower surface of the insulating layer 11 in the support substrate 10. As illustrated in FIG. 3B, the groove 45 is filled with the coating film 18, and the lower surface 10L of the support substrate 10 is covered with the coating film 18. For forming the coating film 18, for example, chemical vapor deposition (CVD), sputtering, atomic layer deposition (ALD), or the like can be used.

As illustrated in FIG. 3C, a dicing portion 46 where the groove 45 is formed is subjected to full-cut dicing, thereby being separated into a plurality of chips. A width of full-cut dicing is narrower than a width of the groove 45. Therefore, the coating film 18 remains on a side surface of the groove 45.

Next, an excellent effect of the first embodiment will be described.

In the first embodiment, the coating film 18 having low moisture permeability suppresses penetration of moisture into the support substrate 10 made of the polymer. Therefore, the support substrate 10 is less likely to generate expansion due to moisture absorption, and the semiconductor layer 12 is less likely to generate distortion caused by the expansion of the support substrate 10. Thereby, the fluctuation in the electrical characteristics of the semiconductor element 20 due to the distortion of the semiconductor layer 12 is suppressed. In general, inorganic insulating materials have lower moisture permeability than polymers. Therefore, it is preferable to use an inorganic insulating material as the coating film 18. Further, since the semiconductor substrate 41 (FIG. 2A) of the SOI substrate is removed and the support substrate 10 made of an insulating polymer is bonded, high-frequency characteristics can be improved.

Next, results of an evaluation experiment conducted to confirm a moisture resistance performance will be described. The semiconductor device according to the first embodiment and a semiconductor device according to a comparative example were left under a high-temperature and high-humidity environment (temperature: 130° C., humidity: 85%) for a certain time (96 hours), and an amount of change in a threshold voltage of the semiconductor element 20 (FIG. 1) was measured. In the semiconductor device according to the comparative example without the coating film 18, the threshold value decreased by about 0.2 V before and after a humidity test, and the semiconductor device changed from a normally-off type to a normally-on type. In contrast, in the semiconductor device provided with the coating film 18 as in the first embodiment, no change in the threshold voltage was observed before and after the humidity test. The effect of providing the coating film 18 was confirmed by this evaluation experiment.

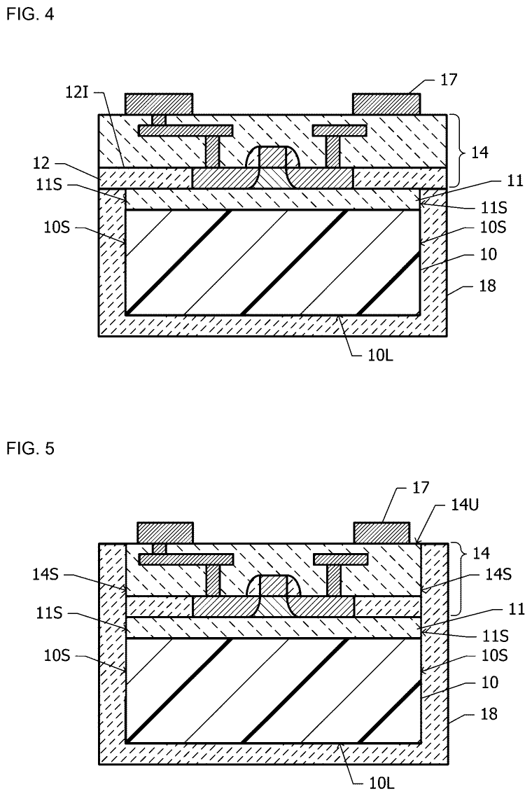

Next, a semiconductor device according to a modified example of the first embodiment will be described with reference to FIG. 4. FIG. 4 is a cross-sectional view of the semiconductor device according to the modified example of the first embodiment. In the first embodiment (FIG. 1), a side surface of the insulating layer 11 is not covered with the coating film 18 and is exposed. In contrast, in the present modified example, the coating film 18 continuously covers the side surface 10S of the support substrate 10 to a side surface 11S of the insulating layer 11. An upper end surface of the coating film 18 is in contact with a lower surface of the element isolation region 12I formed in the semiconductor layer 12.

As in the present modified example, the coating film 18 having low moisture permeability covers the side surface 10S of the support substrate 10 to the side surface 11S of the insulating layer 11, and thus the effect of suppressing penetration of moisture into the support substrate 10 is further enhanced.

### Second Embodiment

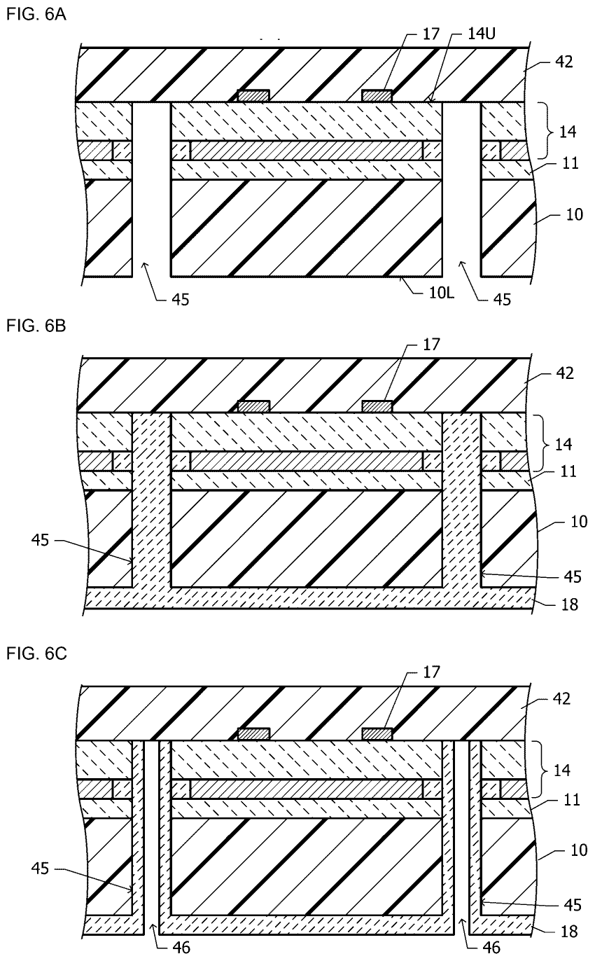

Next, a semiconductor device according to a second embodiment will be described with reference to the drawings from FIG. 5 to FIG. 6C. Hereinafter, description for configurations common to the semiconductor device according to the first embodiment described with reference to the drawings from FIG. 1 to FIG. 3C will be omitted.

FIG. 5 is a cross-sectional view of the semiconductor device according to the second embodiment. In the first embodiment (FIG. 1), the coating film 18 covers the side surface 10S of the support substrate 10, and the side surfaces of the insulating layer 11 and the circuit formation layer 14 are exposed. In contrast, in the second embodiment, a coating film 18 continuously covers a side surface 10S of a support substrate 10 to a side surface 14S of a circuit formation layer 14 via a side surface 11S of an insulating layer 11.

Next, a method of manufacturing the semiconductor device according to the second embodiment will be described with reference to FIG. 6A, FIG. 6B, and FIG. 6C. FIG. 6A, FIG. 6B, and FIG. 6C are cross-sectional views of the semiconductor device at an intermediate stage of a manufacturing process according to the second embodiment.

In the first embodiment, half-cut dicing is performed in the process illustrated in FIG. 3A, but in the second embodiment, full-cut dicing is performed from a lower surface 10L of the support substrate 10 to an upper surface 14U of the circuit formation layer 14 as illustrated in FIG. 6A. Thus, a groove 45 that reaches from the lower surface 10L of the support substrate 10 to a protective tape 42 is formed.

Next, as illustrated in FIG. 6B, the groove 45 is filled with the coating film 18, and the lower surface 10L of the support substrate 10 is covered with the coating film 18. The coating film 18 reaches a bottom surface of the groove 45 (protective tape 42). Thereafter, as illustrated in FIG. 6C, a dicing portion 46 where the groove 45 is formed is subjected to full-cut dicing, thereby being separated into a plurality of chips. The coating film 18 remains on a side surface of the groove 45.

Next, an excellent effect of the second embodiment will be described.

In the second embodiment, since the coating film 18 continuously covers from the side surface 10S of the support substrate 10 to the side surface 14S of the circuit formation layer 14, an effect of suppressing penetration of moisture into the support substrate 10 is further enhanced.

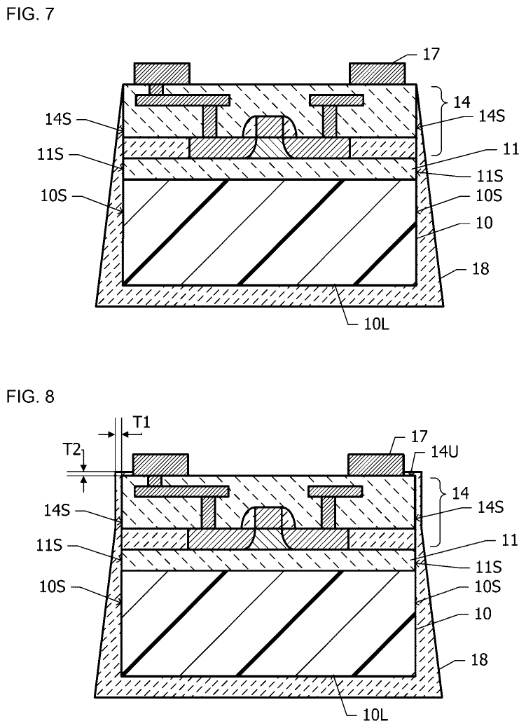

Next, a semiconductor device according to a modified example of the second embodiment will be described with reference to FIG. 7 and FIG. 8.

FIG. 7 is a cross-sectional view of the semiconductor device according to the modified example of the second embodiment. In the second embodiment (FIG. 5), a thickness of a portion of the coating film 18 covering each of the side surface 10S of the support substrate 10, the side surface 11S of the insulating layer 11, and the side surface 14S of the circuit formation layer 14 is approximately constant.

In contrast, in the modified example illustrated in FIG. 7, the thickness of the portion of the coating film 18 covering each of the side surface 10S of the support substrate 10, the side surface 11S of the insulating layer 11, and the side surface 14S of the circuit formation layer 14 gradually becomes thinner from an end portion on a lower surface 10L side of the support substrate 10 toward an end portion on an upper surface 14U side of the circuit formation layer 14. In other words, the thickness of the coating film 18 covering the side surface 10S of the support substrate 10 is thicker than the thickness of the coating film 18 covering each of the side surface 11S of the insulating layer 11 and the side surface 14S of the circuit formation layer 14.

The coating film 18 having distribution of thicknesses illustrated in FIG. 7 is obtained by, for example, employing a film forming method with a low step coverage ratio in a process of forming the coating film 18 illustrated in FIG. 6B. In the present modified example, the thickness of the portion of the coating film 18 covering each of the lower surface 10L and the side surface 10S of the support substrate 10 is sufficiently thick, and thus the effect of suppressing penetration of moisture into the support substrate 10 can be obtained. In addition, since the film forming method with the low step coverage ratio in the process of forming the coating film 18 can be employed, the degree of freedom in selecting the film forming method is increased.

FIG. 8 is a cross-sectional view of a semiconductor device according to another modified example of the second embodiment. In the modified example illustrated in FIG. 8, as in the modified example illustrated in FIG. 7, the thickness of the coating film 18 gradually becomes thinner from an end portion on the lower surface 10L side of the support substrate 10 toward an end portion on the upper surface 14U side of the circuit formation layer 14 and covers a region in the vicinity of an edge of the upper surface 14U of the circuit formation layer 14. A thickness T2 of a portion of the coating film 18 covering the upper surface 14U is equal to or less than a thickness of a portion of the coating film 18 covering the side surface 14S of the circuit formation layer 14.

When the groove 45 illustrated in FIG. 6A is formed, a gap may be generated at an interface between the protective tape 42 and the circuit formation layer 14 around the groove 45. The coating film 18 covering the upper surface 14U of the circuit formation layer 14 is formed by, for example, a film forming material filling the gap when the coating film 18 is formed. In this way, the coating film 18 may cover the region in the vicinity of the edge of the upper surface 14U of the circuit formation layer 14.

### Third Embodiment

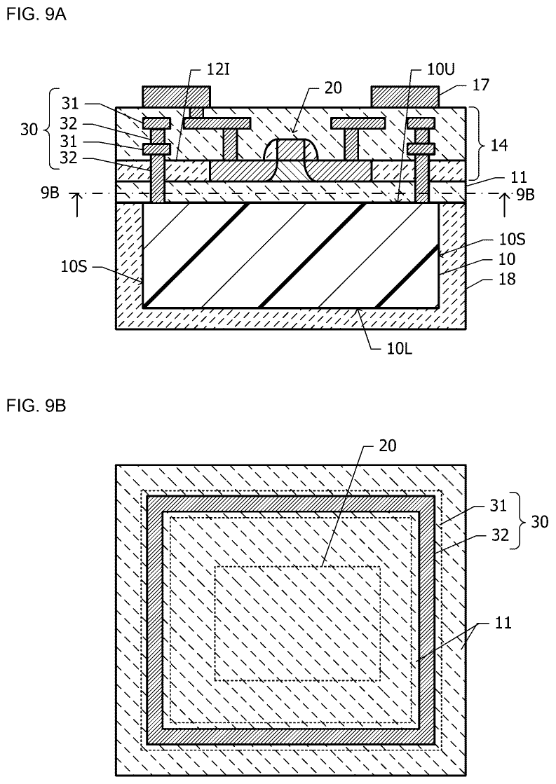

Next, a semiconductor device according to a third embodiment will be described with reference to FIG. 9A and FIG. 9B. Hereinafter, description for configurations common to the semiconductor device according to the first embodiment described with reference to the drawings from FIG. 1 to FIG. 3C will be omitted.

FIG. 9A is a cross-sectional view of the semiconductor device according to the third embodiment, and FIG. 9B is a plan cross-sectional view taken along a dashed-dotted line 9B-9B in FIG. 9A. In the semiconductor device according to the third embodiment, as illustrated in FIG. 9A, a lower surface 10L and a side surface 10S of a support substrate 10 are covered with a coating film 18, as in the semiconductor device according to the first embodiment (FIG. 1).

A guard ring 30 is provided that reaches from an inside of a circuit formation layer 14, passing through an insulating layer 11 in a thickness direction, to an upper surface 10U of the support substrate 10. The guard ring 30 can be formed by using a general semiconductor manufacturing process before removing a semiconductor substrate 41 (FIG. 2A) of an SOI substrate. The guard ring 30 is formed of, for example, metal, nitride, polycrystalline silicon, or the like.

The guard ring 30 includes a plurality of outer peripheral wirings 31 disposed in a plurality of wiring layers of the circuit formation layer 14, and a plurality of outer peripheral vias 32 disposed in a plurality of via layers, an element isolation region 12I, and the insulating layer 11. Each of the outer peripheral wiring 31 and the outer peripheral via 32 (FIG. 9B) continuously surrounds a semiconductor element 20 when the upper surface 10U of the support substrate 10 is viewed in plan view. That is, when the upper surface 10U of the support substrate 10 is viewed in plan view, the guard ring 30 (FIG. 9B) continuously surrounds the semiconductor element 20.

Next, an excellent effect of the third embodiment will be described.

In the third embodiment, the guard ring 30 suppresses penetration of moisture from side surfaces of the insulating layer 11 and the circuit formation layer 14. Therefore, moisture resistance of the semiconductor device can be enhanced.

Each of the above-described embodiments is merely exemplification, and it is needless to say that partial replacement or combination of the configurations described in different embodiments is possible. The same or similar operation and effect by the same or similar configuration of the plurality of embodiments will not be described for each embodiment. Further, the present disclosure is not limited to the embodiments described above. For example, it is obvious to those skilled in the art that various modifications, improvements, combinations, and the like are possible.

What is claimed is:

1. A semiconductor device, comprising:
a support substrate including a polymer or a filler-containing polymer;
an insulating layer including an inorganic insulating material and being on an upper surface which is one surface of the support substrate;
a circuit formation layer including a semiconductor element on the insulating layer; and
a coating film covering a lower surface and a side surface of the support substrate, the lower surface being on an opposite side from the upper surface, and the coating film including a material having lower moisture permeability than the support substrate.

2. The semiconductor device according to claim 1, wherein
the coating film further covers from the side surface of the support substrate to a side surface of the insulating layer.

3. The semiconductor device according to claim 2, wherein
the coating film further covers from the side surface of the insulating layer to a side surface of the circuit formation layer.

4. The semiconductor device according to claim 3, wherein
a thickness of a portion of the coating film covering each of the side surfaces of the support substrate, the insulating layer, and the circuit formation layer becomes thinner from the support substrate toward the circuit formation layer.

5. The semiconductor device according to claim 1, further comprising:
a guard ring reaching from an inside of the circuit formation layer, passing through the insulating layer in a thickness direction, to the upper surface of the support substrate and continuously surrounding the semiconductor element when the upper surface of the support substrate being viewed in plan view.

6. The semiconductor device according to claim 2, further comprising:
a guard ring reaching from an inside of the circuit formation layer, passing through the insulating layer in a thickness direction, to the upper surface of the support substrate and continuously surrounding the semiconductor element when the upper surface of the support substrate being viewed in plan view.

7. The semiconductor device according to claim 3, further comprising:
a guard ring reaching from an inside of the circuit formation layer, passing through the insulating layer in a thickness direction, to the upper surface of the support substrate and continuously surrounding the semiconductor element when the upper surface of the support substrate being viewed in plan view.

8. The semiconductor device according to claim 4, further comprising:
a guard ring reaching from an inside of the circuit formation layer, passing through the insulating layer in a thickness direction, to the upper surface of the support substrate and continuously surrounding the semiconductor element when the upper surface of the support substrate being viewed in plan view.

9. A semiconductor device, comprising:
a support substrate including a polymer or a filler-containing polymer;
an insulating layer including an inorganic insulating material and being on an upper surface which is one surface of the support substrate;
a circuit formation layer including a semiconductor element on the insulating layer; and
a coating film covering a lower surface and a side surface of the support substrate, the lower surface being on an opposite side from the upper surface, and the coating film including an inorganic insulating material.

10. The semiconductor device according to claim 9, wherein
the coating film further covers from the side surface of the support substrate to a side surface of the insulating layer.

11. The semiconductor device according to claim 10, wherein
the coating film further covers from the side surface of the insulating layer to a side surface of the circuit formation layer.

12. The semiconductor device according to claim 11, wherein
a thickness of a portion of the coating film covering each of the side surfaces of the support substrate, the insulating layer, and the circuit formation layer becomes thinner from the support substrate toward the circuit formation layer.

13. The semiconductor device according to claim 9, further comprising:
a guard ring including metal, the guard ring reaching from an inside of the circuit formation layer, passing through the insulating layer in a thickness direction, to the upper surface of the support substrate and continuously surrounding the semiconductor element when the upper surface of the support substrate being viewed in plan view.

14. The semiconductor device according to claim 10, further comprising:
a guard ring including metal, the guard ring reaching from an inside of the circuit formation layer, passing through the insulating layer in a thickness direction, to the upper surface of the support substrate and continuously surrounding the semiconductor element when the upper surface of the support substrate being viewed in plan view.

15. The semiconductor device according to claim 11, further comprising:
a guard ring including metal, the guard ring reaching from an inside of the circuit formation layer, passing through the insulating layer in a thickness direction, to the upper surface of the support substrate and continuously surrounding the semiconductor element when the upper surface of the support substrate being viewed in plan view.

16. The semiconductor device according to claim 12, further comprising:
a guard ring including metal, the guard ring reaching from an inside of the circuit formation layer, passing through the insulating layer in a thickness direction, to the upper surface of the support substrate and continuously surrounding the semiconductor element when the upper surface of the support substrate being viewed in plan view.
